(19) United States
(12) Patent Application Publication
(10) Pub. No.: US 2025/0219581 A1
(43) Pub. Date: Jul. 3, 2025

(54) OSCILLATOR ARRAY COUPLING THROUGH FERROELECTRIC CAPACITORS

(71) Applicant: Intel Corporation, Santa Clara, CA (US)

(72) Inventors: Dmitri Evgenievich Nikonov, Beaverton, OR (US); Amir Khosrowshahi, San Francisco, CA (US); Hai Li, Portland, OR (US); Ian Alexander Young, Olympia, WA (US); Mahendra DC, Portland, OR (US); Punyashloka Debashis, Hillsboro, OR (US); Yu-Ching Liao, Portland, OR (US)

(73) Assignee: Intel Corporation, Santa Clara, CA (US)

(21) Appl. No.: 18/401,187

(22) Filed: Dec. 29, 2023

(51) Int. Cl. H03B 21/01; G06G 7/163; H03B 5/24

(52) U.S. Cl. CPC H03B 21/01; G06G 7/163; H03B 5/24; H03B 2200/004; H03B 2201/0208

(57) ABSTRACT

An apparatus comprising a first electrical oscillator, a second electrical oscillator, at least one ferroelectric capacitor coupled between the first electrical oscillator and the second electrical oscillator, a ferroelectric capacitor of the at least one ferroelectric capacitor comprising a first terminal, a second terminal, and a ferroelectric material between the first terminal and the second terminal; and a detector coupled to the first electrical oscillator and second electrical oscillator, the detector to produce an output based on a state of the first electrical oscillator and the second electrical oscillator.

### BACKGROUND

Combinatorial optimization problems arise in many contexts, including logistics, resource allocation, communication network design, finance, drug discovery, transportation systems, artificial intelligence, electronic design automation, and cryptography. In some instances, digital computing may be used to provide optimal or near optimal solutions to such problems. However, in some instances, analog circuitry may be better suited for solving certain types of optimization problems than a digital computer. For example, a digital computer (e.g., based on a von Neumann architecture) may struggle to solve combinatorial optimization problems in an efficient manner due to a need for exponential computational power.

### BRIEF DESCRIPTION OF THE DRAWINGS

FIGS. 1A-1C illustrate example coupling configurations that couple multiple oscillators to a central node through ferroelectric capacitors, in accordance with any of the embodiments disclosed herein.

FIG. 2 illustrates multiple oscillators coupled to a detector and to a central node through ferroelectric capacitors, in accordance with any of the embodiments disclosed herein.

FIG. 3 illustrates a portion of an Ising machine with oscillator nodes connected via ferroelectric capacitors, in accordance with any of the embodiments disclosed herein.

FIG. 4 illustrates example electrical oscillators coupled through a ferroelectric capacitor and a detector, in accordance with any of the embodiments disclosed herein.

FIG. 5 illustrates a dot product circuit comprising oscillators and ferroelectric capacitors, in accordance with any of the embodiments disclosed herein.

FIG. 6 provides a schematic illustration of a cross-sectional view of an example integrated circuit device, in accordance with any of the embodiments disclosed herein.

FIG. 7 is a top view of a wafer and dies that may be included in a microelectronic assembly, in accordance with any of the embodiments disclosed herein.

FIG. 8 is a cross-sectional side view of an integrated circuit device that may be included in a microelectronic assembly, in accordance with any of the embodiments disclosed herein.

FIGS. 9A-9D are perspective views of example planar, FinFET, gate-all-around, and stacked gate-all-around transistors.

FIG. 10 is a cross-sectional side view of an integrated circuit device assembly that may include a microelectronic assembly, in accordance with any of the embodiments disclosed herein.

FIG. 11 is a block diagram of an example electrical device that may include a microelectronic assembly, in accordance with any of the embodiments disclosed herein.

### DETAILED DESCRIPTION

Some of the most computationally challenging problems belong to the field of optimization, in which a large number of variables may be present. Many of these optimization problems belong to the class of NP-hard problems (e.g., problems that cannot be solved in the time interval which has a polynomial dependence on the number of variables), especially problems pertaining to graphs and having additional constraints to satisfy. Such problems may include classical mathematics problems such as max-cut, Boolean satisfiability, factoring of integer numbers to prime ones, and the traveling salesman problem, among others. These problems generally have similarities with real-life problems in various contexts, such as social networks, logistics, communication networks, transportation and logistics, advertising, information security, and other areas.

Many real-world problems may be posed as graph analytics, wherein node/vertices represent entities and connections/edges between the nodes represent relationships between entities. These problems may be impractical to solve using conventional digital computing. While algorithms do exist for solving optimization problems with digital computing, the time and energy consumed in solving a problem typically scales with an exponential dependence on the number of variables in the problem. Analog computing may be adapted for solving such problems by representing the optimization as energy evolution in a physical system and finding the state of lowest energy.

As one example, a Boolean satisfiability problem may be written in conjunctive normal form as the product (AND) of clauses/constraints where each clause is the Boolean sum (OR) of literals (a variable or its negation). A Boolean satisfiability problem in conjunctive normal form may map to a higher-order Ising model in which each higher-order interaction represents a clause. As Ising models were originally proposed to model ferromagnetic material, an Ising model may include a network of coupled bipolar variables. An Ising model can be implemented on hardware known as an Ising machine. Ising machines may be efficient for finding optimal or near-optimal solutions to difficult combinatorial optimization problems.

To map a combinatorial optimization problem to circuitry, the objective of the problem is formulated as the energy function of an Ising model. In an Ising machine, variables of an optimization function may be represented as spins (or magnetic dipoles) on a grid with connections between pairs of spins. The optimization objective function corresponds to the Hamiltonian energy of a spin system. The spin states may be updated (e.g., in an iterative and probabilistic manner) until a satisfactory ground state (e.g., at a local energy minima) is found and the spin states may represent a solution to the optimization problem.

One way to implement an Ising machine involves using an array of electrical oscillators (e.g., complementary metal-oxide-semiconductor (CMOS) ring oscillators) coupled together. An energy equation for the Ising machine may comprehend bi-linear terms containing spins of a pair of oscillators. However, the objective functions for optimization problems often have higher-order terms and involve more than two variables. In some cases, these terms can be reduced to pairwise terms by introducing one or more auxiliary variables. As an example, consider the exclusive OR (XOR) logic circuit with three variables: inputs of S₁ and S₂ and an output of S₃. The objective function (e.g., energy function) for the circuit may be expressed as:

$$E ( {s}_{1} , {s}_{2} , {s}_{3} ) = \frac{1 + {s}_{1} {s}_{2} {s}_{3}}{2}$$

This energy function is a third-order model as it requires the product of 3 variables simultaneously. The energy function can be rewritten as a second-order model (requiring the product of only two variables at a time) by introducing an auxiliary variable S₄:

$$E ( {s}_{1} , {s}_{2} , {s}_{3} , {s}_{4} ) = {s}_{4} ( - {s}_{1} - {s}_{2} + {s}_{3} + 1 ) + \frac{{s}_{1}}{2} ( {s}_{2} - {s}_{3} - 1 ) + \frac{{s}_{2}}{2} ( - {s}_{3} - 1 ) + {s}_{3} + 2$$

While the reduction of the order may simplify interactions between oscillators (e.g., since each interaction only involves two oscillators), the additional variable increases the routing complexity significantly for the corresponding Ising machine (e.g., by increasing the number of oscillators and the number of connections between oscillators). Indeed, for a larger number of variables and terms, the number of auxiliary variables may greatly exceed the number of actual variables in the original problem. Implementation in analog circuitry of higher order energy functions may significantly simplify an architecture in terms of routing and oscillators required, especially when a large number of auxiliary variables are avoided.

Various embodiments of the present disclosure provide architectures for solving optimization problems. The architectures may couple electrical oscillators together using one or more ferroelectric capacitors. Utilizing a passive element (e.g., a ferroelectric capacitor) to couple oscillators together may provide power savings relative to using active components (e.g., transistors arranged in an inverter configuration) to couple oscillators together, as the passive elements do not have to connect a supply voltage to a ground and thus consume less energy. Use of ferroelectric capacitors as a coupling element may also allow implementation of a circuit for higher order terms (e.g., 3^{rd} and 4^{th} power terms) of an objective function, and thus fewer variables to implement (which may result in reduced circuit area). Ferroelectric capacitors may also enable the coupling of more than two oscillators together to implement higher order variable interactions.

Standard dielectric capacitors have a very linear relationship between an applied electric field and polarization, such that an applied field causes displacement in the ions (ionic polarization), and removal of the field causes the ions to return to their original positions. The energy stored in a dielectric capacitor is a quadratic function of the voltage difference across the terminals of the capacitor: E=C(V₁−V₂)²=C(V₁²+V₂²−2V₁V₂). Accordingly, dielectric capacitors are generally suited to implement bi-linear terms of an objective function and pairwise couplings only.

However, capacitors with ferroelectric materials exhibit spontaneous polarization, caused by permanent dipoles that exist without an applied field. Therefore, ferroelectric capacitors display a nonlinear hysteresis effect of polarization with an applied field. Thus, ferroelectric capacitors have non-linear capacitance that varies with the applied voltage.

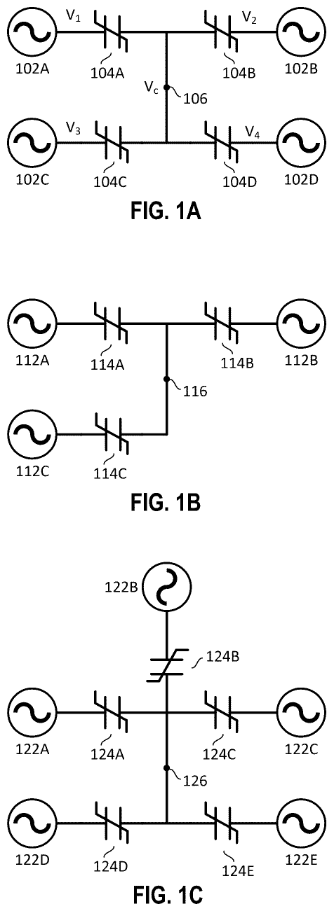

These properties of ferroelectric materials may be leveraged to provide higher order coupling between electrical oscillators. In some instances, the polarization in a ferroelectric capacitor may be a higher order function of the applied electric field, e.g., including the 4th, 6th, etc. powers. As an example of higher order coupling, FIG. 1 illustrates four electrical oscillators 102 (e.g., 102A-D) that are coupled to a central node 106. For each electrical oscillator 102, a respective ferroelectric capacitor 104 (e.g., one of 104A-104D) is coupled between the electrical oscillator 102 and the central node 106. In various embodiments, a ferroelectric capacitor 104 may be connected directly to (e.g. with nothing or only a passive interconnect in between) the respective oscillator 102 and/or the central node 106.

The energy expression for a ferroelectric capacitor 104A in this configuration may be (in part): E=C(V₁−V_{c})²+D(V₁−V_{c})⁴+ . . . where V₁ is the voltage on the side of the ferroelectric capacitor 104A on the oscillator side, V_{c} is the voltage on the side of the ferroelectric capacitor 104A on the side of the central node 106, and C and D are constants dependent on the material used in the capacitor. Each capacitor may contribute the following terms (among other terms) into the energy E= . . . +D(3V₁−V₂−V₃−V₄)⁴+ . . . ˜−12DV₁V₂V₃V₄, where V₂, V₃, and V₄ are voltages at the other capacitors 104B-104D. Now the objective function may include the product of up to four variables. Even higher order coupling is possible by utilizing higher powers of non-linearity, though such terms are typically smaller than the dominant 2^{nd} and 4^{th} terms.

Another advantage of ferroelectric capacitors is the potential for a high dielectric constant (e.g., the ferroelectric material may also be intrinsically dielectric and/or a ferroelectric capacitor may include a dielectric material in addition to the ferroelectric material), allowing for increased capacitance and energy storage in a smaller footprint relative to a standard dielectric capacitor. Thus, large arrays of pairwise connections between electrical oscillators or other architectures may also benefit from coupling via ferroelectric oscillators.

Examples of ferroelectric materials that may be used in capacitors include, e.g., BaTiO₃, AlScN, doped HfO₂, a 2D ferroelectric material such as CuInP₂S₆ or In₂Se₃, another perovskite ferroelectric material such as BiFeO₃, LaₓBi₁₋ₓFeO₃, or BaₓSr₁₋ₓTiO₃, or a superlattice of a ferroelectric and a dielectric material, e.g., [SrTiO₃/PbTiO₃]ₙ.

FIGS. 1B and 1C illustrate additional configurations for coupling multiple electrical oscillators to a central node through ferroelectric capacitors. In FIG. 1B, three electrical oscillators 112A-C are each coupled to a central node 116 through a respective ferroelectric capacitor 114A-C. In FIG. 1C, five electrical oscillators 112A-E are each coupled to a central node 126 through a respective ferroelectric capacitor 124A-E.

In other embodiments, additional oscillators (e.g., six, seven, etc.) could be coupled to the same circuit node through respective ferroelectric capacitors.

In various embodiments, a circuit (e.g., an Ising machine or other circuit) implementing an objective function may utilize any one or more of the coupling schemes described herein (including three or more electrical oscillators coupled through respective ferroelectric capacitors to a central node and/or pairwise coupling of electrical oscillators through a ferroelectric capacitor) depending on the function to be implemented.

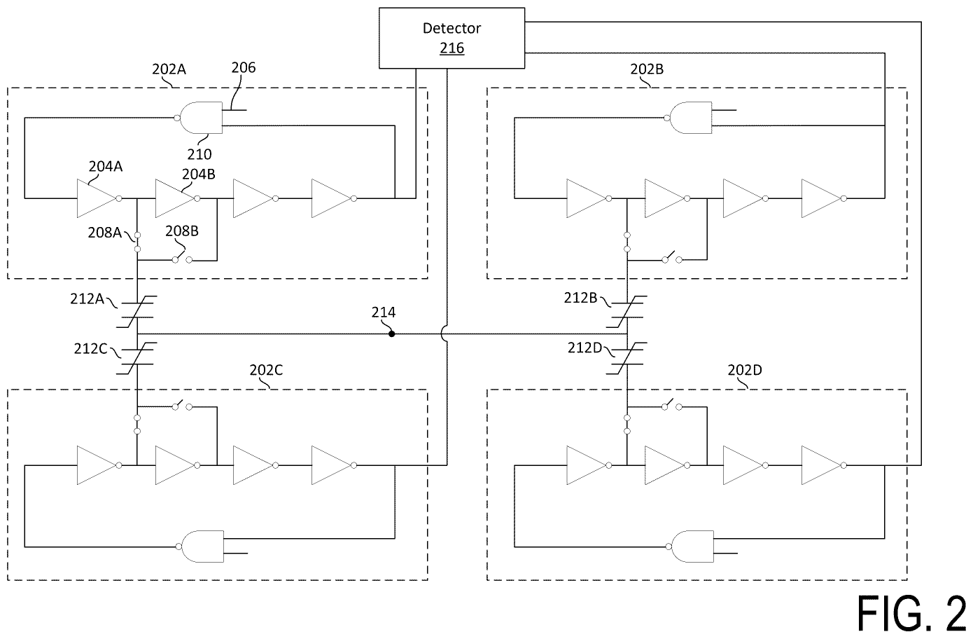

FIG. 2 illustrates multiple oscillators 202 coupled to a detector 216 and to a central node 214 through ferroelectric capacitors 212, in accordance with any of the embodiments disclosed herein. FIG. 2 illustrates one example of the architecture shown in FIG. 1A.

The architecture includes a first electrical oscillator 202A coupled to a central node 214 through a first ferroelectric capacitor 212A, a second electrical oscillator 202B coupled to the central node 214 through a second ferroelectric capacitor 212B, third electrical oscillator 202C coupled to a central node 214 through a third ferroelectric capacitor 212C, and fourth electrical oscillator 202D coupled to a central node 214 through a fourth ferroelectric capacitor 212D.

In the embodiment depicted, the oscillators 202 are shown as CMOS ring oscillators. For example, oscillator 202A includes a plurality of inverter stages 204 arranged in a ring. In other embodiments, any suitable oscillator architecture may be used, such as a Hopf oscillator (e.g., an oscillator that includes dynamic oscillator amplitudes), a Van der Pol oscillator, or a Kuramoto oscillator (e.g., with fixed oscillator amplitudes), or other suitable oscillator type.

The oscillators 202 also each include an enable signal 206 coupled to a NAND gate 210. Enable signal 206 may be considered a local enable signal and when asserted may result in the oscillator 202A generating an oscillating signal that is output to detector 216. In other embodiments, a global enable signal may also be present.

In various embodiments, the stage of each oscillator that is coupled to the central node may be configurable through, e.g., switches (e.g., 208A, 208B). For example, depending on the configuration, either the output of stage 204A or the output of stage 204B may be coupled to the central node, depending on which switch of 208A and 208B is closed. The respective switches of the different oscillators may be operated independently. Such an embodiment may allow for positive or negative coupling from the oscillators, depending on the implementation of the circuit. In other embodiments, the coupling of the oscillators to the central node may be hard wired.

The architecture also includes a detector 216 that is coupled to each of the oscillators 202. The detector 216 may sample the outputs of the oscillators and determine any suitable characteristic of these outputs. For example, the detector 216 may include a phase detector that samples the phases of the outputs. In some embodiments, the detector 216 may determine whether the output of an oscillator is in phase or out of phase. In some embodiments, the phase of the oscillator corresponds to a binary value for a variable corresponding to the oscillator (e.g., the phase may represent a spin state of an Ising machine).

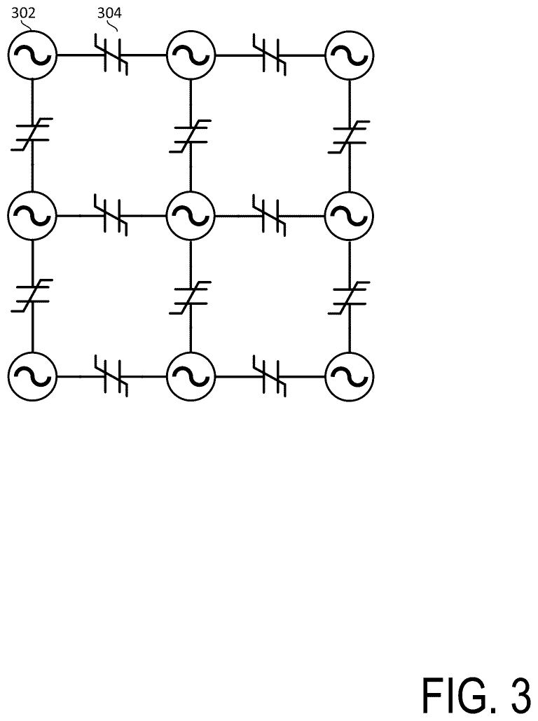

FIG. 3 illustrates a portion of an Ising machine with oscillator nodes coupled via ferroelectric capacitors 304, in accordance with any of the embodiments disclosed herein. In this embodiment, the oscillators 302 are coupled to other oscillators in a pairwise fashion. Such an embodiment may result in stronger coupling between the oscillators and/or a reduction in circuit area due to the use of ferroelectric capacitors 304.

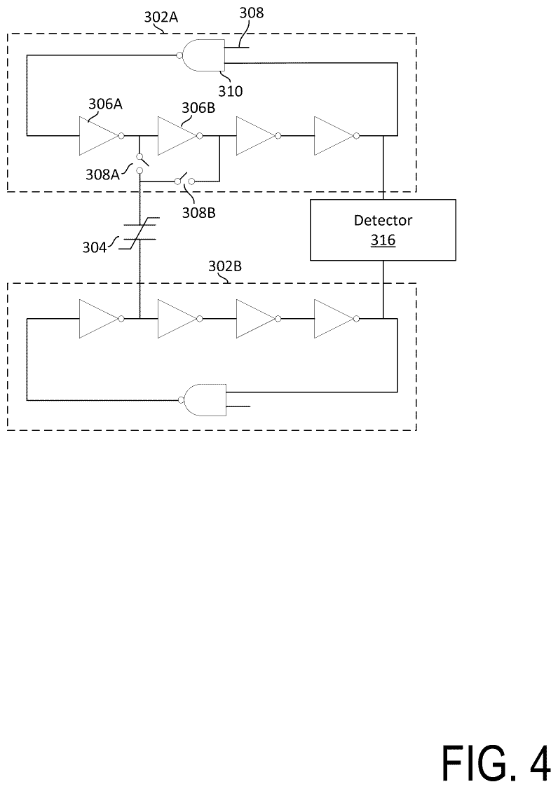

FIG. 4 illustrates example electrical oscillators coupled through a ferroelectric capacitor and a detector, in accordance with any of the embodiments disclosed herein. This FIG. illustrates an example coupling between a pair of oscillators 302 of FIG. 3.

The architecture includes a first electrical oscillator 302A coupled to a second electrical oscillator 302B through a ferroelectric capacitor 304.

In the embodiment depicted, the oscillators 302 are shown as CMOS ring oscillators. For example, each oscillator includes a plurality of inverter stages 306 arranged in a ring. In other embodiments, other suitable oscillator architectures may be used.

The oscillators 302 also each include an enable signal 308 coupled to a NAND gate 310. Enable signal 308 may be considered a local enable signal and when asserted may result in the oscillator 302A generating an oscillating signal that is output to detector 316. In other embodiments, a global enable signal may also be present that is provided to a plurality of oscillators to enable or disable the oscillators.

In various embodiments, the stage of the oscillator 302A that is coupled to the other oscillator 302B may be configurable through, e.g., switches (e.g., 308A, 308B). For example, depending on the configuration, either the output of stage 306A or the output of stage 306B may be coupled to the oscillator 302B, depending on which switch of 308A and 308B is closed. When the switch 308A is closed and 308B is open the oscillators may have a positive coupling and when switch 308A is open and 308B is closed the oscillators may have a negative coupling.

The architecture also includes a detector 316 that is coupled to each of the oscillators 302. The detector 316 may sample the outputs of the oscillators and determine any suitable characteristic of these outputs. For example, the detector 316 may include a phase detector that samples the phases of the outputs. In some embodiments, the detector 316 may determine whether the outputs of the oscillators are in phase or out of phase. In various embodiments, the phases of the oscillators correspond to binary values for variables corresponding to the respective oscillators.

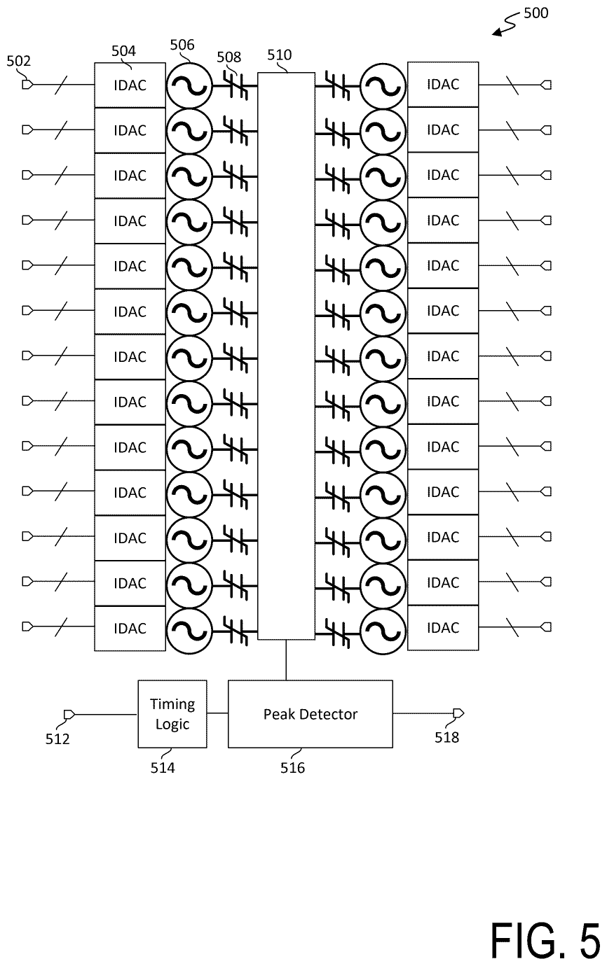

FIG. 5 illustrates a dot product circuit 500 comprising oscillators 506 and ferroelectric capacitors 508, in accordance with any of the embodiments disclosed herein. The circuit 500 comprises an array of current-based digital-to-analog converters (IDACs) 504, oscillators 506, and ferroelectric capacitors 508.

The circuit accepts data inputs 502 for a dot product. For example, the left side and right side of data inputs may accept dot product input data and the output may represent a dot product of the two vectors. The circuit may utilize frequency shift keying (FSK) of the oscillators 506 to infer a dot product based on the data inputs 502. An IDAC 504 may accept a data input (e.g., an encoded input that is based on a difference between an element of a first vector and a corresponding element of a second vector) and output a current that is used to control a frequency of the oscillator 506 coupled to the IDAC. The oscillators are coupled together via the ferroelectric capacitors 508 to an averager node 510. In some embodiments, the capacitance of the ferroelectric capacitors may be tunable to facilitate synchronization of the oscillators 506.

The averager node 510 may sum the oscillator signal outputs. In some embodiments, the averager node 510 may comprise a low resistance metal plate or other suitable conductive structure.

The timing logic 514 may control the peak detector 516 to capture the oscillation amplitude on the averager node and drive the output signal 518. For example, the peak detector 516 may detect the magnitude of an analog output envelope of an ac signal at the averager node 510. This output may correlate with the value of the dot product.

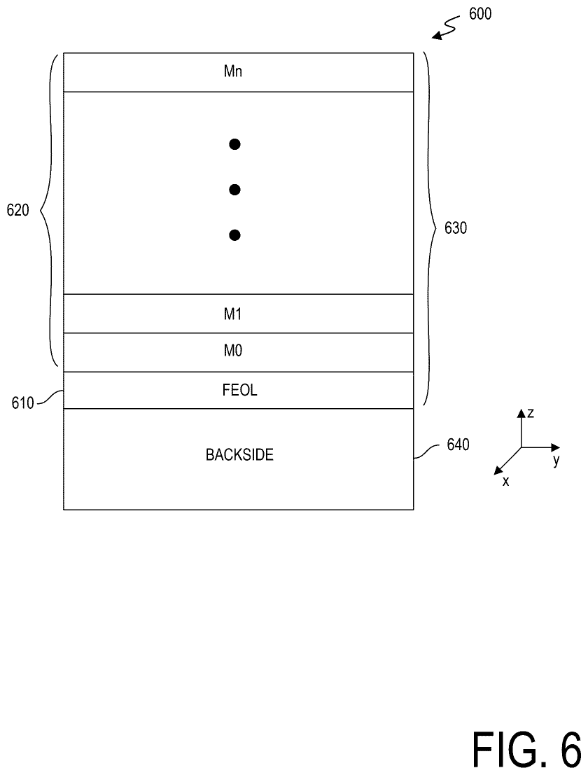

FIG. 6 provides a schematic illustration of a cross-sectional view of an example integrated circuit device (e.g., a chip) 600 that may include oscillator arrays coupled through ferroelectric capacitors as articulated herein. The IC device 600 may include transistors as well as other circuit elements (e.g., resistors, diodes, capacitors, inductors, etc.).

As shown in FIG. 6, the IC device 600 may include a front side 630 comprising a front-end-of-line (FEOL) 610 that includes various logic layers, circuits, and devices to drive and control a logic IC. These circuits and devices may be configured for any number of functions, such as logic or compute transistors, input/output (I/O) transistors, access or switching transistors, and/or radio frequency (RF) transistors, to name a few examples. According to some embodiments, in addition to these devices and circuits, FEOL 610 may include, for example, one or more other layers or structures associated with the semiconductor devices and circuits. For example, the FEOL can also include a substrate and one or more dielectric layers that surround active and/or conductive portions of the devices and circuits. The FEOL may also include one or more conductive contacts that provide electrical contact to transistor elements such as gate structures, drain regions, or source regions. The FEOL may also include local interconnect (e.g., vias or lines) that connect contacts to interconnect features within a back-end-of-line (BEOL) 620.

The front side 630 of the IC device 600 also includes a BEOL 620 including various metal interconnect layers (e.g., metal 0 through metal n, where n is any suitable integer). Various metal layers of the BEOL 620 may be used to interconnect the various inputs and outputs of the FEOL 610.

Generally speaking, each of the metal layers of the BEOL 620, e.g., each of the layers M0-Mn shown in FIG. 6, may include a via portion and a trench/interconnect portion. Typically, the trench portion of a metal layer is above the via portion, but, in other embodiments, a trench portion may be provided below a via portion of any given metal layer of the BEOL 620. The trench portion of a metal layer may be configured for transferring signals and power along metal lines (also sometimes referred to as “trenches”) extending in the x-y plane (e.g., in the x or y directions), while the via portion of a metal layer may be configured for transferring signals and power through metal vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL 620, e.g., layers M0-Mn shown in FIG. 6, may include certain patterns of conductive metals, e.g., copper (Cu) or aluminum (Al), or metal alloys, or more generally, patterns of an electrically conductive material (e.g., including carbon based materials), formed in an insulating medium such as an interlayer dielectric (ILD). The insulating medium may include any suitable ILD materials such as silicon oxide, silicon nitride, aluminum oxide, and/or silicon oxynitride. In various embodiments, any one or more of these layers may additionally include active devices (e.g., transistors, diodes) and/or passive devices (e.g., capacitors, resistors, inductors).

The IC device 600 may also include a backside 640. For example, the backside 640 may formed on the opposite side of a wafer from the front side 630. In various embodiments, the backside 640 may include any suitable elements to assist operation of the IC device 600. For example, the backside 640 may include various metal layers to deliver power to logic of the FEOL 610.

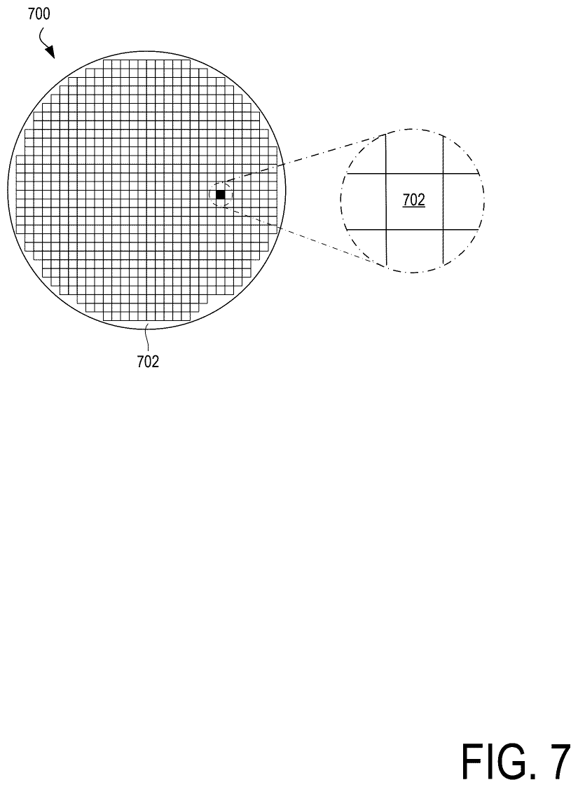

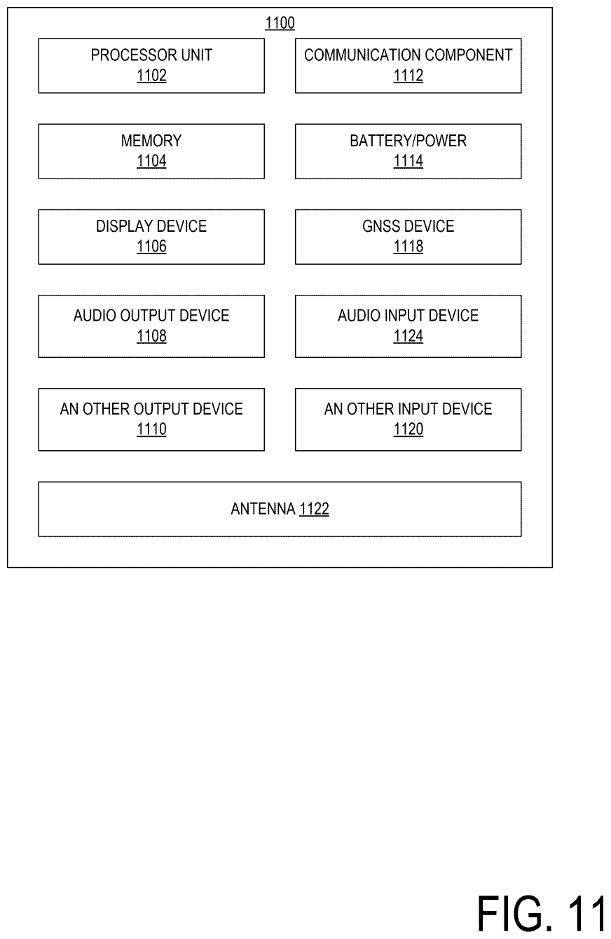

FIG. 7 is a top view of a wafer 700 and dies 702, wherein individual dies may include electrical oscillator arrays coupled through ferroelectric capacitors as disclosed herein. The wafer 700 may be composed of semiconductor material and may include one or more dies 702 having integrated circuit structures formed on a surface of the wafer 700. The individual dies 702 may be a repeating unit of an integrated circuit product that includes any suitable integrated circuit. After the fabrication of the semiconductor product is complete, the wafer 700 may undergo a singulation process in which the dies 702 are separated from one another to provide discrete “chips” of the integrated circuit product. The die 702 may include one or more transistors, supporting circuitry to route electrical signals to the transistors, passive components (e.g., signal traces, resistors, capacitors, or inductors), and/or any other integrated circuit components. In some embodiments, the wafer 700 or the die 702 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 702. For example, a memory array formed by multiple memory devices may be formed on a same die 702 as a processor unit (e.g., the processor unit 1102 of FIG. 11) or other logic that is configured to store information in the memory devices or execute instructions stored in the memory array. In some embodiments, various ones of the microelectronic assemblies disclosed herein may be manufactured using a die-to-wafer assembly technique in which some dies are attached to a wafer 700 that include other dies, and the wafer 700 is subsequently singulated.

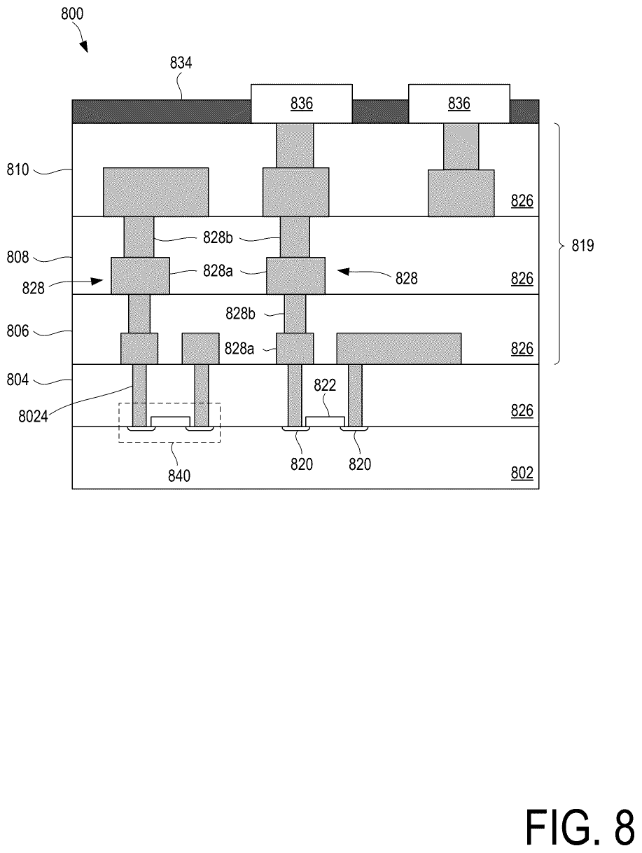

FIG. 8 is a cross-sectional side view of an integrated circuit device 800 that may include electrical oscillator arrays coupled through ferroelectric capacitors as disclosed herein. One or more of the integrated circuit devices 800 may be included in one or more dies 702 (FIG. 7). The integrated circuit device 800 may be formed on a die substrate 802 (e.g., the wafer 700 of FIG. 7) and may be included in a die (e.g., the die 702 of FIG. 7). The die substrate 802 may be a semiconductor substrate composed of semiconductor material systems including, for example, n-type or p-type materials systems (or a combination of both). The die substrate 802 may include, for example, a crystalline substrate formed using a bulk silicon or a silicon-on-insulator (SOI) substructure. In some embodiments, the die substrate 802 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 802. Although a few examples of materials from which the die substrate 802 may be formed are described here, any material that may serve as a foundation for an integrated circuit device 800 may be used. The die substrate 802 may be part of a singulated die (e.g., the dies 702 of FIG. 7) or a wafer (e.g., the wafer 700 of FIG. 7).

The integrated circuit device 800 may include one or more device layers 804 disposed on the die substrate 802. The device layer 804 may include features of one or more transistors 840 (e.g., metal oxide semiconductor field-effect transistors (MOSFETs)) formed on the die substrate 802. The transistors 840 may include, for example, one or more source and/or drain (S/D) regions 820, a gate 822 to control current flow between the S/D regions 820, and one or more S/D contacts 824 to route electrical signals to/from the S/D regions 820. The transistors 840 may include additional features not depicted for the sake of clarity, such as device isolation regions, gate contacts, and the like. The transistors 840 are not limited to the type and configuration depicted in FIG. 8 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

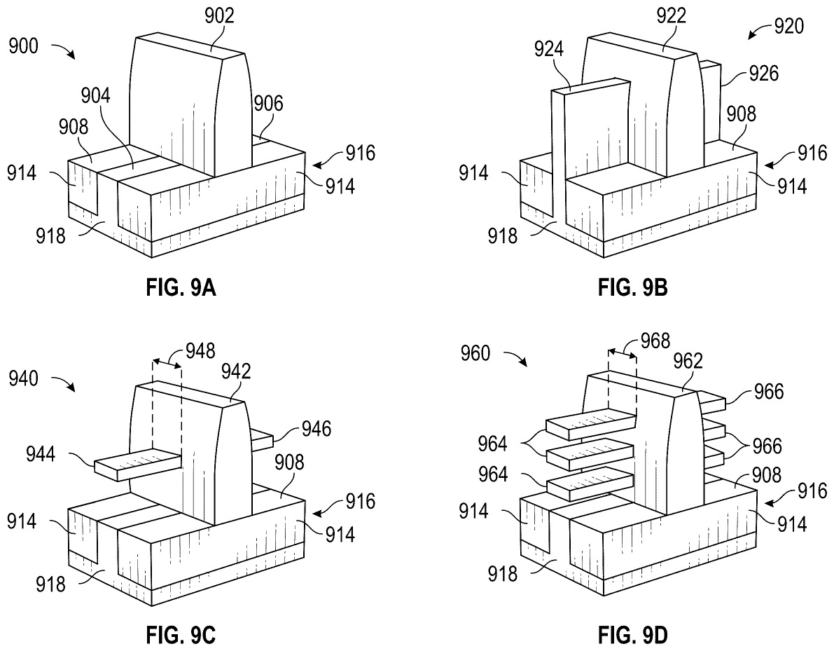

FIGS. 9A-9D are simplified perspective views of example planar, FinFET, gate-all-around, and stacked gate-all-around transistors. The transistors illustrated in FIGS. 9A-9D are formed on a substrate 916 having a surface 908. Isolation regions 914 separate the source and drain regions of the transistors from other transistors and from a bulk region 918 of the substrate 916.

FIG. 9A is a perspective view of an example planar transistor 900 comprising a gate 902 that controls current flow between a source region 904 and a drain region 906. The transistor 900 is planar in that the source region 904 and the drain region 906 are planar with respect to the substrate surface 908.

FIG. 9B is a perspective view of an example FinFET transistor 920 comprising a gate 922 that controls current flow between a source region 924 and a drain region 926. The transistor 920 is non-planar in that the source region 924 and the drain region 926 comprise “fins” that extend upwards from the substrate surface 928. As the gate 922 encompasses three sides of the semiconductor fin that extends from the source region 924 to the drain region 926, the transistor 920 can be considered a tri-gate transistor. FIG. 9B illustrates one S/D fin extending through the gate 922, but multiple S/D fins can extend through the gate of a FinFET transistor.

FIG. 9C is a perspective view of a gate-all-around (GAA) transistor 940 comprising a gate 942 that controls current flow between a source region 944 and a drain region 946. The transistor 940 is non-planar in that the source region 944 and the drain region 946 are elevated from the substrate surface 928.

FIG. 9D is a perspective view of a GAA transistor 960 comprising a gate 962 that controls current flow between multiple elevated source regions 964 and multiple elevated drain regions 966. The transistor 960 is a stacked GAA transistor as the gate controls the flow of current between multiple elevated S/D regions stacked on top of each other. The transistors 940 and 960 are considered gate-all-around transistors as the gates encompass all sides of the semiconductor portions that extends from the source regions to the drain regions. The transistors 940 and 960 can alternatively be referred to as nanowire, nanosheet, or nanoribbon transistors depending on the width (e.g., widths 948 and 968 of transistors 940 and 960, respectively) of the semiconductor portions extending through the gate.

Returning to FIG. 8, a transistor 840 may include a gate 822 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 840 is to be a p-type metal oxide semiconductor (PMOS) or an n-type metal oxide semiconductor (NMOS) transistor. In some implementations, the gate electrode may consist of or comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 840 along the source-channel-drain direction, the gate electrode may consist of or comprise a U-shaped structure that includes a bottom portion substantially parallel to the surface of the die substrate 802 and two sidewall portions that are substantially perpendicular to the top surface of the die substrate 802. In other embodiments, at least one of the metal layers that form the gate electrode may simply be a planar layer that is substantially parallel to the top surface of the die substrate 802 and does not include sidewall portions substantially perpendicular to the top surface of the die substrate 802. In other embodiments, the gate electrode may consist of or comprise a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 820 may be formed within the die substrate 802 adjacent to the gate 822 of individual transistors 840. The S/D regions 820 may be formed using an implantation/diffusion process or an etching/deposition process, for example. In the former process, dopants such as boron, aluminum, antimony, phosphorous, or arsenic may be ion-implanted into the die substrate 802 to form the S/D regions 820. An annealing process that activates the dopants and causes them to diffuse farther into the die substrate 802 may follow the ion-implantation process. In the latter process, the die substrate 802 may first be etched to form recesses at the locations of the S/D regions 820. An epitaxial deposition process may then be carried out to fill the recesses with material that is used to fabricate the S/D regions 820. In some implementations, the S/D regions 820 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 820 may be formed using one or more alternate semiconductor materials such as germanium or a group III-V material or alloy. In further embodiments, one or more layers of metal and/or metal alloys may be used to form the S/D regions 820.

Electrical signals, such as power and/or input/output (I/O) signals, may be routed to and/or from the devices (e.g., transistors 840) of the device layer 804 through one or more interconnect layers disposed on the device layer 804 (illustrated in FIG. 8 as interconnect layers 806-810). For example, electrically conductive features of the device layer 804 (e.g., the gate 822 and the S/D contacts 824) may be electrically coupled with the interconnect structures 828 of the interconnect layers 806-810. The one or more interconnect layers 806-810 may form a metallization stack (also referred to as an “ILD stack”) 819 of the integrated circuit device 800.

The interconnect structures 828 (e.g., lines) may be arranged within the interconnect layers 806-810 to route electrical signals according to a wide variety of designs; in particular, the arrangement is not limited to the particular configuration of interconnect structures 828 depicted in FIG. 8. Although a particular number of interconnect layers 806-810 is depicted in FIG. 8, embodiments of the present disclosure include integrated circuit devices having more or fewer interconnect layers than depicted.

In some embodiments, the interconnect structures 828 may include lines 828a and/or vias 828b filled with an electrically conductive material such as a metal. The lines 828a may be arranged to route electrical signals in a direction of a plane that is substantially parallel with a surface of the die substrate 802 upon which the device layer 804 is formed. For example, the lines 828a may route electrical signals in a direction in and out of the page and/or in a direction across the page. The vias 828b may be arranged to route electrical signals in a direction of a plane that is substantially perpendicular to the surface of the die substrate 802 upon which the device layer 804 is formed. In some embodiments, the vias 828b may electrically couple lines 828a of different interconnect layers 806-810 together.

The interconnect layers 806-810 may include a dielectric material 826 disposed between the interconnect structures 828, as shown in FIG. 8. In some embodiments, dielectric material 826 disposed between the interconnect structures 828 in different ones of the interconnect layers 806-810 may have different compositions; in other embodiments, the composition of the dielectric material 826 between different interconnect layers 806-810 may be the same. The device layer 804 may include a dielectric material 826 disposed between the transistors 840 and a bottom layer of the metallization stack as well. The dielectric material 826 included in the device layer 804 may have a different composition than the dielectric material 826 included in the interconnect layers 806-810; in other embodiments, the composition of the dielectric material 826 in the device layer 804 may be the same as a dielectric material 826 included in any one of the interconnect layers 806-810.

A first interconnect layer 806 (referred to as Metal 1 or “M1”) may be formed directly on the device layer 804. In some embodiments, the first interconnect layer 806 may include lines 828a and/or vias 828b, as shown. The lines 828a of the first interconnect layer 806 may be coupled with contacts (e.g., the S/D contacts 824) of the device layer 804. The vias 828b of the first interconnect layer 806 may be coupled with the lines 828a of a second interconnect layer 808.

The second interconnect layer 808 (referred to as Metal 2 or “M2”) may be formed directly on the first interconnect layer 806. In some embodiments, the second interconnect layer 808 may include via 828b to couple the lines 828 of the second interconnect layer 808 with the lines 828a of a third interconnect layer 810. Although the lines 828a and the vias 828b are structurally delineated with a line within individual interconnect layers for the sake of clarity, the lines 828a and the vias 828b may be structurally and/or materially contiguous (e.g., simultaneously filled during a dual-damascene process) in some embodiments.

The third interconnect layer 810 (referred to as Metal 3 or “M3”) (and additional interconnect layers, as desired) may be formed in succession on the second interconnect layer 808 according to similar techniques and configurations described in connection with the second interconnect layer 808 or the first interconnect layer 806. In some embodiments, the interconnect layers that are “higher up” in the metallization stack 819 in the integrated circuit device 800 (i.e., farther away from the device layer 804) may be thicker that the interconnect layers that are lower in the metallization stack 819, with lines 828a and vias 828b in the higher interconnect layers being thicker than those in the lower interconnect layers.

The integrated circuit device 800 may include a solder resist material 834 (e.g., polyimide or similar material) and one or more conductive contacts 836 formed on the interconnect layers 806-810. In FIG. 8, the conductive contacts 836 are illustrated as taking the form of bond pads. The conductive contacts 836 may be electrically coupled with the interconnect structures 828 and configured to route the electrical signals of the transistor(s) 840 to external devices. For example, solder bonds may be formed on the one or more conductive contacts 836 to mechanically and/or electrically couple an integrated circuit die including the integrated circuit device 800 with another component (e.g., a printed circuit board). The integrated circuit device 800 may include additional or alternate structures to route the electrical signals from the interconnect layers 806-810; for example, the conductive contacts 836 may include other analogous features (e.g., posts) that route the electrical signals to external components.

In some embodiments in which the integrated circuit device 800 is a double-sided die, the integrated circuit device 800 may include another metallization stack (not shown) on the opposite side of the device layer(s) 804. This metallization stack may include multiple interconnect layers as discussed above with reference to the interconnect layers 806-810, to provide conductive pathways (e.g., including conductive lines and vias) between the device layer(s) 804 and additional conductive contacts (not shown) on the opposite side of the integrated circuit device 800 from the conductive contacts 836.

In other embodiments in which the integrated circuit device 800 is a double-sided die, the integrated circuit device 800 may include one or more through silicon vias (TSVs) through the die substrate 802; these TSVs may make contact with the device layer(s) 804, and may provide conductive pathways between the device layer(s) 804 and additional conductive contacts (not shown) on the opposite side of the integrated circuit device 800 from the conductive contacts 836. In some embodiments, TSVs extending through the substrate can be used for routing power and ground signals from conductive contacts on the opposite side of the integrated circuit device 800 from the conductive contacts 836 to the transistors 840 and any other components integrated into the integrated circuit device (e.g., die) 800, and the metallization stack 819 can be used to route I/O signals from the conductive contacts 836 to transistors 840 and any other components integrated into the integrated circuit device (e.g., die) 800.

Multiple integrated circuit devices 800 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

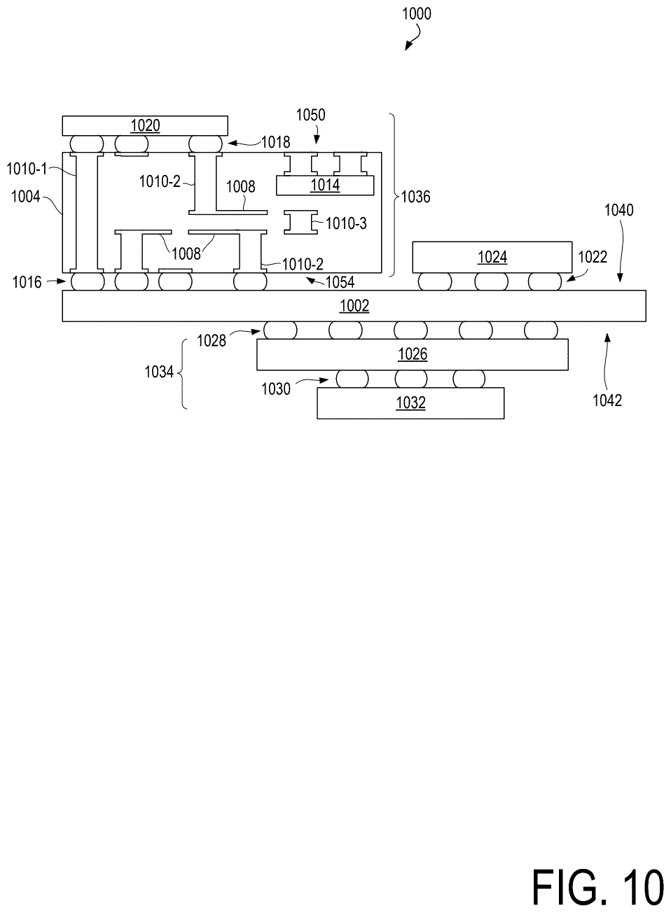

FIG. 10 is a cross-sectional side view of an integrated circuit device assembly 1000 that may include electrical oscillator arrays coupled through ferroelectric capacitors as disclosed herein. In some embodiments, the integrated circuit device assembly 1000 may be a microelectronic assembly. The integrated circuit device assembly 1000 includes a number of components disposed on a circuit board 1002 (which may be a motherboard, system board, mainboard, etc.). The integrated circuit device assembly 1000 includes components disposed on a first face 1040 of the circuit board 1002 and an opposing second face 1042 of the circuit board 1002; generally, components may be disposed on one or both faces 1040 and 1042.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1002. In other embodiments, the circuit board 1002 may be a non-PCB substrate. The integrated circuit device assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002, and may include solder balls (as shown in FIG. 10), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1036 may include an integrated circuit component 1020 coupled to an interposer 1004 by coupling components 1018. The coupling components 1018 may take any suitable form for the application, such as the forms discussed above with reference to the coupling components 1016. Although a single integrated circuit component 1020 is shown in FIG. 10, multiple integrated circuit components may be coupled to the interposer 1004; indeed, additional interposers may be coupled to the interposer 1004. The interposer 1004 may provide an intervening substrate used to bridge the circuit board 1002 and the integrated circuit component 1020.

The integrated circuit component 1020 may be a packaged or unpackaged integrated circuit product that includes one or more integrated circuit dies (e.g., the die 702 of FIG. 7, the integrated circuit device 800 of FIG. 8) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1020, a single monolithic integrated circuit die comprises solder bumps attached to contacts on the die. The solder bumps allow the die to be directly attached to the interposer 1004. The integrated circuit component 1020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1020 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1004 may spread connections to a wider pitch or reroute a connection to a different connection. For example, the interposer 1004 may couple the integrated circuit component 1020 to a set of ball grid array (BGA) conductive contacts of the coupling components 1016 for coupling to the circuit board 1002. In the embodiment illustrated in FIG. 10, the integrated circuit component 1020 and the circuit board 1002 are attached to opposing sides of the interposer 1004; in other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias 1010, including but not limited to through hole vias 1010-1 (that extend from a first face 1050 of the interposer 1004 to a second face 1054 of the interposer 1004), blind vias 1010-2 (that extend from the first or second faces 1050 or 1054 of the interposer 1004 to an internal metal layer), and buried vias 1010-3 (that connect internal metal layers).

In some embodiments, the interposer 1004 can comprise a silicon interposer. Through silicon vias (TSV) extending through the silicon interposer can connect connections on a first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art.

The integrated circuit device assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit device assembly 1000 illustrated in FIG. 10 includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

FIG. 11 is a block diagram of an example electrical device 1100 that may include electrical oscillator arrays coupled through ferroelectric capacitors as disclosed herein. For example, any suitable components of the electrical device 1100 may include one or more of the integrated circuit device assemblies 1000, integrated circuit components 1020, integrated circuit devices 800, integrated circuit dies 702, or other components disclosed herein. A number of components are illustrated in FIG. 11 as included in the electrical device 1100, but any one or more of these components may be omitted or duplicated, as suitable for the application. In some embodiments, some or all of the components included in the electrical device 1100 may be attached to one or more motherboards mainboards, or system boards. In some embodiments, one or more of these components are fabricated onto a single system-on-a-chip (SoC) die.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the processor unit 1102. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1100 can comprise one or more processor units 1102 that are heterogeneous or asymmetric to another processor unit 1102 in the electrical device 1100. There can be a variety of differences between the processing units 1102 in a system in terms of a spectrum of metrics of merit including architectural, microarchitectural, thermal, power consumption characteristics, and the like. These differences can effectively manifest themselves as asymmetry and heterogeneity among the processor units 1102 in the electrical device 1100.

In some embodiments, the electrical device 1100 may include a communication component 1112 (e.g., one or more communication components). For example, the communication component 1112 can manage wireless communications for the transfer of data to and from the electrical device 1100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as amplitude modulation (AM) or frequency modulation (FM) radio transmissions).

In some embodiments, the communication component 1112 may manage wired communications, such as electrical, optical, or any other suitable communication protocols (e.g., IEEE 802.3 Ethernet standards). As noted above, the communication component 1112 may include multiple communication components. For instance, a first communication component 1112 may be dedicated to shorter-range wireless communications such as Wi-Fi or Bluetooth, and a second communication component 1112 may be dedicated to longer-range wireless communications such as global positioning system (GPS), EDGE, GPRS, CDMA, WiMAX, LTE, EV-DO, or others. In some embodiments, a first communication component 1112 may be dedicated to wireless communications, and a second communication component 1112 may be dedicated to wired communications.

The electrical device 1100 may include battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System (GNSS) device 1118 (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include an other output device 1110 (or corresponding interface circuitry, as discussed above). Examples of the other output device 1110 may include an audio codec, a video codec, a printer, a wired or wireless transmitter for providing information to other devices, or an additional storage device.

The electrical device 1100 may include an other input device 1120 (or corresponding interface circuitry, as discussed above). Examples of the other input device 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1100 may be any other electronic device that processes data. In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

It will also be understood that, although the terms “first,” “second,” and so forth may be used herein to describe various elements, these elements should not be limited by these terms. These terms are only used to distinguish one element from another, and are not intended to imply that the objects so described must be in a given sequence, either temporally, spatially, in ranking or in any other manner. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. For example, the phrase “A and/or B” means (A), (B), or (A and B), while the phrase “A, B, and/or C” means (A), (B), (C), (A and B), (A and C), (B and C), or (A, B, and C).

As used throughout this description, and in the claims, a list of items joined by the term “at least one of” or “one or more of” can mean any combination of the listed terms.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Furthermore, the terms “comprising,” “including,” “having,” and the like, as used with respect to embodiments of the present disclosure, are synonymous.

The description may use the phrases “in an embodiment,” “according to some embodiments,” “in accordance with embodiments,” or “in embodiments,” which may each refer to one or more of the same or different embodiments.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 107 Siemens per meter (S/m) at 20 degrees Celsius. Examples of such materials include Cu, Ag, Al, Au, W, Zn and Ni.

The term “signal” may refer to at least one current signal, voltage signal, magnetic signal, or data/clock signal.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices.

The description may use perspective-based descriptions such as top/bottom, in/out, over/under, and the like. Such descriptions are merely used to facilitate the discussion and are not intended to restrict the application of embodiments described herein to any particular orientation.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer means that at least a part of the first material or layer is in direct physical contact with at least a part of that second material/layer. Similar distinctions are to be made in the context of component assemblies.

As used herein, “A is proximate to B” may mean that A is adjacent to B or A is otherwise near to B.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

The terms “substantially,” “close,” “approximately,” “near,” and “about,” generally refer to being within +/−10% of a target value (unless specifically specified).

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes an apparatus comprising a first electrical oscillator; a second electrical oscillator; at least one ferroelectric capacitor coupled between the first electrical oscillator and the second electrical oscillator, a ferroelectric capacitor of the at least one ferroelectric capacitor comprising a first terminal, a second terminal, and a ferroelectric material between the first terminal and the second terminal; and a detector coupled to the first electrical oscillator and second electrical oscillator, the detector to produce an output based on a state of the first electrical oscillator and the second electrical oscillator.

Example 2 includes the subject matter of Example 1, and further including a third electrical oscillator and a fourth electrical oscillator, wherein the at least one ferroelectric capacitor includes a first ferroelectric capacitor coupled between the first electrical oscillator and a circuit node, a second ferroelectric capacitor coupled between the second electrical oscillator and the circuit node, a third ferroelectric capacitor coupled between the third electrical oscillator and the circuit node, and a fourth ferroelectric capacitor coupled between the fourth electrical oscillator and the circuit node.

Example 3 includes the subject matter of any of Examples 1 and 2, and further including an Ising machine comprising the first electrical oscillator, second electrical oscillator, at least one ferroelectric capacitor, and detector.

Example 4 includes the subject matter of any of Examples 1-3, and wherein the Ising machine further comprises four ferroelectric capacitors each coupled to a common circuit node through a respective ferroelectric capacitor.

Example 5 includes the subject matter of any of Examples 1-4, and wherein the output of the detector is indicative of a dot product.

Example 6 includes the subject matter of any of Examples 1-5, and wherein the output of the detector comprises an indication of a first phase of the first electrical oscillator and an indication of a second phase of the second electrical oscillator.

Example 7 includes the subject matter of any of Examples 1-6, and wherein the ferroelectric capacitor further comprises a dielectric material between the terminals of the ferroelectric capacitor.

Example 8 includes the subject matter of any of Examples 1-7, and wherein ferroelectric capacitors of the at least one ferroelectric capacitor are substantially the same size.

Example 9 includes the subject matter of any of Examples 1-8, and wherein a first ferroelectric capacitor of the at least one ferroelectric capacitor is different in size from a second ferroelectric capacitor of the at least one ferroelectric capacitor.

Example 10 includes the subject matter of any of Examples 1-9, and wherein the first and second electrical oscillators each comprise a plurality of inverters in series.

Example 11 includes an apparatus comprising a first electrical oscillator coupled to a circuit node through a first capacitor comprising a ferroelectric material; a second electrical oscillator coupled to the circuit node through a second capacitor comprising the ferroelectric material; a third electrical oscillator coupled to the circuit node through a third capacitor comprising the ferroelectric material; and a detector coupled to the first electrical oscillator, second electrical oscillator, and third electrical oscillator, the detector to produce an output based on a state of the first electrical oscillator, second electrical oscillator, and third electrical oscillator.

Example 12 includes the subject matter of Example 11, and further including a fourth electrical oscillator coupled to the circuit node through a fourth capacitor comprising the ferroelectric material, and wherein the output is further based on a state of the fourth electrical oscillator.

Example 13 includes the subject matter of any of Examples 11 and 12, and wherein the output comprises a first indication of a phase of the first electrical oscillator, a second indication of a phase of the second electrical oscillator, and a third indication of a phase of the third electrical oscillator.

Example 14 includes the subject matter of any of Examples 11-13, and wherein the first indication represents a value of a first variable of a combinatorial optimization function, the second indication represents a value of a second variable of the optimization function, and the third indication represents a value of a third variable of the optimization function.

Example 15 includes the subject matter of any of Examples 11-14, and wherein the output of the detector represents a dot product.

Example 16 includes the subject matter of any of Examples 11-15, and further including an Ising machine comprising the first, second, and third electrical oscillators.

Example 17 includes the subject matter of any of Examples 11-16, and wherein the first, second, and third capacitors further comprise a dielectric material.

Example 18 includes the subject matter of any of Examples 11-17, and wherein the first, second, and third capacitors are substantially the same size.

Example 19 includes the subject matter of any of Examples 11-18, and wherein the first, second, and third capacitors are not all substantially the same size.

Example 20 includes the subject matter of any of Examples 11-19, and wherein the first, second, and third electrical oscillators each comprise a plurality of inverters in series.

Example 21 includes a system comprising a plurality of electrical oscillators coupled to a circuit node through a plurality of capacitors comprising a ferroelectric material, wherein a capacitor of the plurality of capacitors is coupled between a respective electrical oscillator and the circuit node; and a detector to generate an output based on a state of the plurality of electrical oscillators.

Example 22 includes the subject matter of Example 21, and further including a processor unit to program a coupling of the plurality of electrical oscillators based on an objective function.

Example 23 includes the subject matter of any of Examples 21 and 22, and further including an integrated circuit die comprising the plurality of electrical oscillators and the plurality of capacitors comprising the ferroelectric material.

Example 24 includes the subject matter of any of Examples 21-23, and further including a circuit board coupled to the integrated circuit die.

Example 25 includes the subject matter of any of Examples 21-24, and further including at least one of a network interface, battery, or memory coupled to the integrated circuit die.

Example 26 includes the subject matter of any of Examples 21-25, and wherein the output comprises indications of phases of the plurality of electrical oscillators.

Example 27 includes the subject matter of any of Examples 21-26, and wherein the indications represent values of variables of a combinatorial optimization function.

Example 28 includes the subject matter of any of Examples 21-27, and wherein the output of the detector represents a dot product.

Example 29 includes the subject matter of any of Examples 21-28, and further including an Ising machine comprising the plurality of electrical oscillators.

Example 30 includes the subject matter of any of Examples 21-29, and wherein the plurality of capacitors further comprise a dielectric material.

Example 31 includes the subject matter of any of Examples 21-30, and wherein the plurality of capacitors are substantially the same size.

Example 32 includes the subject matter of any of Examples 21-31, and wherein the plurality of capacitors are not all substantially the same size.

Example 33 includes the subject matter of any of Examples 21-32, and wherein the plurality of electrical oscillators each comprise a plurality of inverters in series.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

1. An apparatus comprising:
a first electrical oscillator;
a second electrical oscillator;
at least one ferroelectric capacitor coupled between the first electrical oscillator and the second electrical oscillator, a ferroelectric capacitor of the at least one ferroelectric capacitor comprising a first terminal, a second terminal, and a ferroelectric material between the first terminal and the second terminal; and
a detector coupled to the first electrical oscillator and second electrical oscillator, the detector to produce an output based on a state of the first electrical oscillator and the second electrical oscillator.

2. The apparatus of claim 1, further comprising a third electrical oscillator and a fourth electrical oscillator, wherein the at least one ferroelectric capacitor includes a first ferroelectric capacitor coupled between the first electrical oscillator and a circuit node, a second ferroelectric capacitor coupled between the second electrical oscillator and the circuit node, a third ferroelectric capacitor coupled between the third electrical oscillator and the circuit node, and a fourth ferroelectric capacitor coupled between the fourth electrical oscillator and the circuit node.

3. The apparatus of claim 1, further comprising an Ising machine comprising the first electrical oscillator, second electrical oscillator, at least one ferroelectric capacitor, and detector.

4. The apparatus of claim 3, wherein the Ising machine further comprises four ferroelectric capacitors each coupled to a common circuit node through a respective ferroelectric capacitor.

5. The apparatus of claim 1, wherein the output of the detector is indicative of a dot product.

6. The apparatus of claim 1, wherein the output of the detector comprises an indication of a first phase of the first electrical oscillator and an indication of a second phase of the second electrical oscillator.

7. The apparatus of claim 1, wherein the ferroelectric capacitor further comprises a dielectric material between the terminals of the ferroelectric capacitor.

8. The apparatus of claim 1, wherein ferroelectric capacitors of the at least one ferroelectric capacitor are substantially the same size.

9. The apparatus of claim 1, wherein a first ferroelectric capacitor of the at least one ferroelectric capacitor is different in size from a second ferroelectric capacitor of the at least one ferroelectric capacitor.

10. The apparatus of claim 1, wherein the first and second electrical oscillators each comprise a plurality of inverters in series.

11. An apparatus comprising:
a first electrical oscillator coupled to a circuit node through a first capacitor comprising a ferroelectric material;
a second electrical oscillator coupled to the circuit node through a second capacitor comprising the ferroelectric material;
a third electrical oscillator coupled to the circuit node through a third capacitor comprising the ferroelectric material; and
a detector coupled to the first electrical oscillator, second electrical oscillator, and third electrical oscillator, the detector to produce an output based on a state of the first electrical oscillator, second electrical oscillator, and third electrical oscillator.

12. The apparatus of claim 11, further comprising a fourth electrical oscillator coupled to the circuit node through a fourth capacitor comprising the ferroelectric material, and wherein the output is further based on a state of the fourth electrical oscillator.

13. The apparatus of claim 11, wherein the output comprises a first indication of a phase of the first electrical oscillator, a second indication of a phase of the second electrical oscillator, and a third indication of a phase of the third electrical oscillator.

14. The apparatus of claim 13, wherein the first indication represents a value of a first variable of a combinatorial optimization function, the second indication represents a value of a second variable of the optimization function, and the third indication represents a value of a third variable of the optimization function.

15. The apparatus of claim 11, wherein the output of the detector represents a dot product.

16. A system comprising:
a plurality of electrical oscillators coupled to a circuit node through a plurality of capacitors comprising a ferroelectric material, wherein a capacitor of the plurality of capacitors is coupled between a respective electrical oscillator and the circuit node; and
a detector to generate an output based on a state of the plurality of electrical oscillators.

17. The system of claim 16, further comprising a processor unit to program a coupling of the plurality of electrical oscillators based on an objective function.

18. The system of claim 16, further comprising an integrated circuit die comprising the plurality of electrical oscillators and the plurality of capacitors comprising the ferroelectric material.

19. The system of claim 18, further comprising a circuit board coupled to the integrated circuit die.

20. The system of claim 18, further comprising at least one of a network interface, battery, or memory coupled to the integrated circuit die.
